(19) United States
(12) Patent Application Publication
(10) Pub. No.: US 2022/0091498 A1
(43) Pub. Date: Mar. 24, 2022

(54) REFLECTION-TYPE MASK BLANK, REFLECTION-TYPE MASK AND METHOD FOR MANUFACTURING SAME, AND METHOD FOR MANUFACTURING SEMICONDUCTOR DEVICE

(71) Applicant: HOYA CORPORATION, Tokyo (JP)

(72) Inventor: Mizuki KATAOKA, Tokyo (JP)

(73) Assignee: HOYA CORPORATION, Tokyo (JP)

(21) Appl. No.: 17/423,988

(22) PCT Filed: Mar. 6, 2020
(86) PCT No.: PCT/JP2020/009828

§ 371 Date: Jul. 19, 2021

(30) Foreign Application Priority Data
Mar. 13, 2019 (JP) 2019-046108

(51) Int. Cl. G03F 1/24; G03F 1/54; H01L 21/027

(52) U.S. Cl. CPC G03F 1/24; H01L 21/0274; G03F 1/54

(57) ABSTRACT

Provided is a reflection-type mask blank which enables the further reduction of the shadowing effect of a reflection-type mask. A reflection-type mask blank in which a multilayer reflection film and an absorber film are arranged in this order on a substrate, the reflection-type mask blank being characterized in that the absorber film is made from a material comprising an amorphous metal containing at least one element selected from tin (Sn), tantalum (Ta), chromium (Cr), cobalt (Co), nickel (Ni), antimony (Sb), platinum (Pt), iridium (Ir), iron (Fe), gold (Au), aluminum (Al), copper (Cu), zinc (Zn) and silver (Ag) and the absorber film has a film thickness of 55 nm or less.

### CROSS-REFERENCE TO RELATED APPLICATIONS

This application is the National Stage of International Application No. PCT/JP2020/009828, filed Mar. 6, 2020, which claims priority to Japanese Patent Application No. 2019-046108, filed Mar. 13, 2019, and the contents of which is incorporated by reference.

### TECHNICAL FIELD

The present disclosure relates to a reflective mask blank that is an original plate for manufacturing an exposure mask used for manufacturing a semiconductor device or the like, a reflective mask, a method of manufacturing the same, and a method of manufacturing a semiconductor device.

### BACKGROUND ART

Types of light sources of exposure apparatuses in manufacturing semiconductor devices have been evolving while wavelengths thereof have been shortened gradually like a g-line having a wavelength of 436 nm, an i-line having a wavelength of 365 nm, a KrF laser having a wavelength of 248 nm, and an ArF laser having a wavelength of 193 nm. In order to achieve further finer pattern transfer, extreme ultra violet (EUV) lithography using EUV having a wavelength in the neighborhood of 13.5 nm has been developed. In EUV lithography, a reflective mask is used because there are few materials transparent to EUV light. The reflective mask has a multilayer reflective film for reflecting exposure light on a low thermal expansion substrate. The reflective mask has, as a basic structure, a mask structure in which a desired pattern for transfer is formed on a protective film for protecting the multilayer reflective film. In addition, typical examples of the structure of the pattern for transfer include a binary-type reflection mask and a phase shift-type reflection mask (a half-tone phase shift-type reflection mask). The transfer pattern of the binary-type reflection mask includes a relatively thick absorber pattern that sufficiently absorbs EUV light. The transfer pattern of the phase shift-type reflection mask includes a relatively thin absorber pattern that reduces EUV light by light absorption and generates reflected light having a phase substantially inverted (a phase inverted by approximately 180°) with respect to reflected light from the multilayer reflective film. The phase shift-type reflection mask has a resolution improving effect because high transfer optical image contrast can be obtained by a phase shift effect, as with a transmission-type optical phase shift mask. In addition, since the film thickness of the absorber pattern (the phase shift pattern) of the phase shift-type reflection mask is thin, a fine and highly accurate phase shift pattern can be formed.

In EUV lithography, a projection optical system including a large number of reflecting mirrors is used due to light transmittance. Then, EUV light is made obliquely incident on the reflective mask to cause these reflecting mirrors not to block projection light (exposure light). At present, an incident angle is typically 6° with respect to a vertical plane of a reflection mask substrate. Along with the improvement of a numerical aperture (NA) of the projection optical system, studies are being conducted toward making the incident angle about 8° that is a more oblique incident angle.

In EUV lithography, since the exposure light is obliquely incident, there is an inherent problem called a shadowing effect. The shadowing effect is a phenomenon in which exposure light is obliquely incident on an absorber pattern having a three-dimensional structure, whereby a shadow is formed, resulting in changing the dimension and/or position of a pattern to be transferred and formed. The three-dimensional structure of the absorber pattern serves as a wall and a shadow is formed on a shade side, resulting in changing the dimension and/or the position of the pattern to be transferred and formed. For example, a difference occurs in a dimension and position of a transfer pattern between both cases, a case where the orientation of the absorber pattern to be arranged is parallel to a direction of obliquely incident light and a case where the orientation of the absorber pattern to be arranged is perpendicular to the direction of the obliquely incident light, thereby decreasing transfer accuracy.

Patent Literatures 1 to 3 disclose techniques related to such a reflective mask for EUV lithography and a mask blank for manufacturing the same. Additionally, Patent Literature 2 also discloses a shadowing effect. Conventionally, the film thickness of the phase shift pattern is made relatively thin as compared with the case of the binary-type reflection mask, by using the phase shift-type reflection mask as the reflective mask for EUV lithography, whereby a decrease in the transfer accuracy due to the shadowing effect is reduced.

### CITATION LIST

### Patent Literature

Patent Literature 1: JP 2004-039884 A

Patent Literature 2: JP 2007-273678 A

Patent Literature 3: JP 2009-099931 A

### SUMMARY OF DISCLOSURE

The finer the pattern is and the more the accuracy of the pattern dimension and/or the pattern position is improved, the more the electrical characteristics and performance of the semiconductor device increase and the more the degree of integration and a chip size can be reduced. Therefore, EUV lithography is required to have performance of transferring dimension patterns that are more accurate and finer by one step than conventional ones. It is presently required to form an ultra-fine and highly accurate pattern for half pitch 16 nm (hp 16 nm) generation. In response to such a requirement, a further reduction in the film thickness of an absorber film (phase shift film) is required in order to reduce the shadowing effect. In particular, in the case of EUV exposure, the film thickness of the absorber film (the phase shift film) is required to be less than 60 nm and preferably 50 nm or less.

As disclosed in Patent Literatures 1 and 2, Ta has been conventionally used as a material for forming the absorber film (phase shift film) of the reflective mask blank. However, a refractive index n of Ta in EUV light (for example, with a wavelength of 13.5 nm) is approximately 0.943. Therefore, even if a phase shift effect of Ta is used, the film thickness of an absorber film (phase shift film) formed of Ta alone is thinned to 60 nm that is the lowest limit. To make the film thickness of an absorber film thinner, for example, a metal material having a high extinction coefficient k (high absorption effect) can be used as an absorber film of a binary-type reflective mask blank. As disclosed in Patent Literatures 2 and 3, tin (Sn) is one of metal materials having a high extinction coefficient k at a wavelength of 13.5 nm. However, tin (Sn) has a melting point as low as 231° C. and thus its thermal stability is low. Therefore, when tin (Sn) is used as a material of the absorber film, there is a concern about thermal resistance at the time of mask processing and EUV exposure, and there may be posed a problem of lowering the cleaning resistance of the absorber film.

In view of the above points, it is an aspect of the present disclosure to provide a reflective mask blank and a reflective mask manufactured therewith, the reflective mask blank being capable of further reducing the shadowing effect of a reflective mask.

In addition, an aspect of the present disclosure is to provide a reflective mask blank and a reflective mask manufactured therewith, the reflective mask blank being capable of further reducing the shadowing effect of a reflective mask and forming a fine and highly accurate absorber pattern, being excellent in thermal stability, and having higher cleaning resistance. In addition, an aspect of the present disclosure is to provide a method of manufacturing a semiconductor device having a fine and highly accurate transfer pattern by using the reflective mask.

In order to solve the above problems, the present disclosure has the following configurations.

(Configuration 1)

A configuration 1 of the present disclosure is a reflective mask blank including a multilayer reflective film and an absorber film that are provided in the order mentioned on a substrate, in which
the absorber film includes a material including an amorphous metal containing Tin (Sn) and at least one or more elements selected from tantalum (Ta), chromium (Cr), cobalt (Co), nickel (Ni), antimony (Sb), platinum (Pt), iridium (Ir), iron (Fe), gold (Au), aluminum (Al), copper (Cu), zinc (Zn), and silver (Ag), and
the absorber film has a film thickness of 55 nm or less.

(Configuration 2)

A configuration 2 of the present disclosure is the reflective mask blank according to the configuration 1, in which content of the tin (Sn) is 10 atomic % or more and 90 atomic % or less.

(Configuration 3)

A configuration 3 of the present disclosure is the reflective mask blank according to the configuration 1 or 2, in which the absorber film has an extinction coefficient of 0.035 or more, and the amorphous metal contains tin (Sn) and at least one or more elements selected from tantalum (Ta), chromium (Cr), platinum (Pt), iridium (Ir), iron (Fe), gold (Au), aluminum (Al), and zinc (Zn).

(Configuration 4)

A configuration 4 of the present disclosure is the reflective mask blank according to the configuration 1 or 2, in which the absorber film has an extinction coefficient of 0.045 or more, and the amorphous metal contains tin (Sn) and at least one or more elements selected from cobalt (Co), nickel (Ni), antimony (Sb), copper (Cu), and silver (Ag).

(Configuration 5)

A configuration 5 of the present disclosure is the reflective mask blank according to any one of the configurations 1 to 3, in which the amorphous metal contains tin (Sn) and at least one or more elements selected from tantalum (Ta) and chromium (Cr), and content of the tantalum (Ta) in the amorphous metal is more than 15 atomic %.

(Configuration 6)

A configuration 6 of the present disclosure is the reflective mask blank according to any one of the configurations 1 to 5, in which the amorphous metal contains nitrogen (N), and content of the nitrogen (N) in the amorphous metal is 2 atomic % or more and 55 atomic % or less.

(Configuration 7)

A configuration 7 of the present disclosure is the reflective mask blank according to any one of the configurations 1 to 6, in which a protective film is provided between the multilayer reflective film and the absorber film.

(Configuration 8)

A configuration 8 of the present disclosure is the reflective mask blank according to any one of the configurations 1 to 7, in which an etching mask film is provided on the absorber film, and the etching mask film includes a material including a material including chromium (Cr) or a material including silicon (Si).

(Configuration 9)

A configuration 9 of the present disclosure is a reflective mask having an absorber pattern in which the absorber film in the reflective mask blank according to any one of the configurations 1 to 8 is patterned.

(Configuration 10)

A configuration 10 of the present disclosure is a method of manufacturing a reflective mask, the method including: forming an absorber pattern by patterning the absorber film of the reflective mask blank according to any one of the configurations 1 to 8 by dry etching using a chlorine-based gas.

(Configuration 11)

A configuration 11 of the present disclosure is a method of manufacturing a semiconductor device, the method including: a step of setting the reflective mask according to the configuration 9 in an exposure apparatus having an exposure light source that emits EUV light and transferring a transfer pattern to a resist film formed on a transfer-receiving substrate.

According to the present disclosure, it is possible to provide a reflective mask blank and a reflective mask manufactured therewith, the reflective mask blank being capable of further reducing the shadowing effect of a reflective mask.

In addition, according to the present disclosure, it is possible to provide a reflective mask blank and a reflective mask manufactured therewith, the reflective mask blank being capable of further reducing the shadowing effect of a reflective mask and forming a fine and highly accurate absorber pattern, being excellent in thermal stability, and having higher cleaning resistance. In addition, according to the present disclosure, it is possible to provide a method of manufacturing a semiconductor device having a fine and highly accurate transfer pattern by using the reflective mask.

### BRIEF DESCRIPTION OF DRAWINGS

FIG. 1 is a schematic cross-sectional diagram of a main part for describing a schematic configuration of a reflective mask blank according to the present disclosure.

FIGS. 2(a) to 2(d) are each a step diagram showing, in a schematic cross-sectional diagram, a main part of a step of manufacturing a reflective mask from the reflective mask blank.

FIG. 3 is a diagram showing a relationship between the thickness of an absorber film including a SnTa film and the reflectance for light having a wavelength of 13.5 nm.

FIG. 4 is a diagram showing a relationship between the thickness of an absorber film including a SnNiN film and the reflectance for light having a wavelength of 13.5 nm.

FIG. 5 is a diagram showing a relationship between the thickness of an absorber film including a SnCo film and the reflectance for light having a wavelength of 13.5 nm.

FIG. 6 is a schematic cross-sectional diagram of a main part showing another example of the reflective mask blank according to the present disclosure.

FIGS. 7(a) to 7(e) are each a step diagram showing, in a schematic cross-sectional diagram, a main part of a step of manufacturing a reflective mask from the reflective mask blank illustrated in FIG. 6.

FIG. 8 is a schematic cross-sectional diagram of a main part showing still another example of the reflective mask blank according to the present disclosure.

FIGS. 9(a) to 9(e) are each a step diagram showing, in a schematic cross-sectional diagram, a main part of a step of manufacturing a reflective mask from the reflective mask blank illustrated in FIG. 8.

### DESCRIPTION OF EMBODIMENTS

Hereinafter, embodiments of the present disclosure will be specifically described with reference to the drawings. Note that each of the following embodiments is one mode for embodying the present disclosure and does not limit the present disclosure within the scope thereof. Note that in the drawings, the same or corresponding parts are denoted by the same reference signs, and description thereof may be simplified or omitted.

<Configuration of Reflective Mask Blank and Method of Manufacturing the Same>

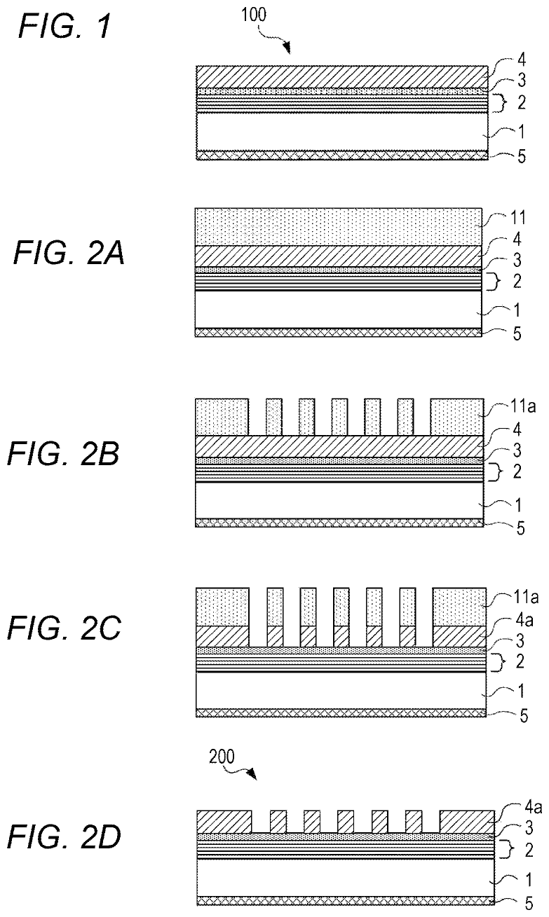

FIG. 1 is a schematic cross-sectional diagram of a main part for describing a configuration of a reflective mask blank 100 according to an embodiment of the present disclosure. As shown in the figure, the reflective mask blank 100 includes a substrate 1, a multilayer reflective film 2, a protective film 3, and an absorber film 4 that are layered in this order, the multilayer reflective film 2 being formed on a side of a first main surface (front surface) and reflecting EUV light that is exposure light, the protective film 3 being provided to protect the multilayer reflective film 2 and formed of a material having resistance to an etchant used when the absorber film 4 is patterned as described later and to a cleaning liquid, and the absorber film 4 absorbing EUV light. In addition, a conductive back film 5 for an electrostatic chuck is formed on a side of a second main surface (a back surface) of the substrate 1.

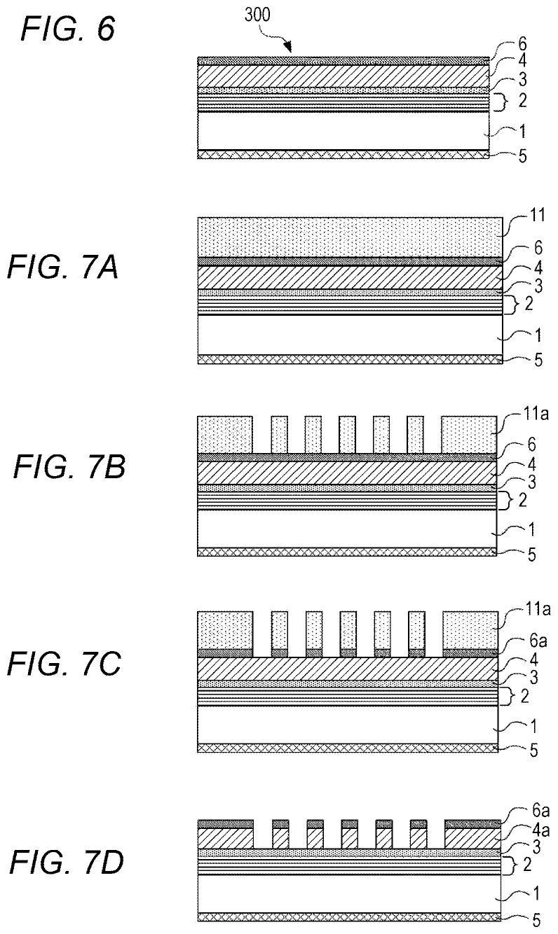

FIG. 6 is a schematic cross-sectional diagram of a main part showing another example of the reflective mask blank according to the present disclosure. Similarly to the reflective mask blank 100 shown in FIG. 1, a reflective mask blank 300 includes a substrate 1, a multilayer reflective film 2, a protective film 3, an absorber film 4, and a conductive back film 5. The reflective mask blank 300 shown in FIG. 6 further has an etching mask film 6, which serves as an etching mask for the absorber film 4 when the absorber film 4 is etched, on the absorber film 4. Note that in a case where the reflective mask blank 300 having the etching mask film 6 is used, the etching mask film 6 may be peeled off after a transfer pattern is formed on the absorber film 4 as described later.

FIG. 8 is a schematic cross-sectional diagram of a main part showing still another example of the reflective mask blank according to the present disclosure. Similarly to the reflective mask blank 300 shown in FIG. 6, a reflective mask blank 500 includes a substrate 1, a multilayer reflective film 2, a protective film 3, an absorber film 4, an etching mask film 6, and a conductive back film 5. The reflective mask blank 500 shown in FIG. 8 further has an etching stopper film 7, which serves as an etching stopper when the absorber film 4 is etched, between the protective film 3 and the absorber film 4. Note that in a case where the reflective mask blank 500 having the etching mask film 6 and the etching stopper film 7 is used, the etching mask film 6 and/or the etching stopper film 7 may be peeled off after a transfer pattern is formed on the absorber film 4 as described later.

Additionally, the above-described reflective mask blanks 100, 300, and 500 each include a configuration in which the conductive back film 5 is not formed. Furthermore, the above-described reflective mask blanks 100, 300, and 500 each include a configuration of a mask blank with a resist film in which a resist film 11 is formed on the absorber film 4 or the etching mask film 6 as illustrated in FIGS. 2(a), 7(a), and 9(a).

In the present specification, for example, the description of “the multilayer reflective film 2 formed on a main surface of the substrate 1” means that the multilayer reflective film 2 is arranged in contact with a surface of the substrate 1 and also means that that another film is provided between the substrate 1 and the multilayer reflective film 2. The same applies to other films. Additionally, in the present specification, for example, the expression of “a film A is arranged on a film B while the film A is in contact with the film B” means that the film A and the film B are arranged in direct contact with each other without another film interposed between the film A and the film B.

Individual configurations of the reflective mask blanks 100, 300, and 500 (which may be simply referred to as “reflective mask blank 100”) will be described below in detail.

<<Substrate>>

As the substrate 1, a substrate having a low thermal expansion coefficient in the range of 0±5 ppb/° C. is preferably used in order to prevent distortion of an absorber pattern due to heat at the time of exposure to EUV light. As the material having a low thermal expansion coefficient in this range, for example, SiO₂—TiO₂-based glass and multicomponent glass ceramics can be used.

In view of obtaining at least pattern transfer accuracy and position accuracy, a first main surface on a side of the substrate 1 where a transfer pattern (constituted by the absorber pattern 4a to be described later) is formed has been subjected to a surface treatment so that the first main surface has high flatness. In the case of EUV exposure, flatness in an area of 132 mm×132 mm or 142 mm×142 mm of the main surface on the side of the substrate 1 where the transfer pattern is formed is preferably 0.1 μm or less, more preferably 0.05 μm or less, and particularly preferably 0.03 μm or less. In addition, the second main surface on a side opposite to the side on which the absorber film 4 is formed is the surface that is electrostatically chucked when the reflective mask is set in an exposure apparatus. Flatness in an area having a size of 132 mm×132 mm or 142 mm×142 mm of the second main surface is preferably 0.1 μm or less, more preferably 0.05 μm or less, and particularly preferably 0.03 μm or less.

In addition, high surface smoothness of the substrate 1 is also an extremely important item. Surface roughness of the first main surface of the substrate 1 on which the absorber pattern 4a for transfer is formed is preferably a root mean square roughness (RMS) of 0.1 nm or less. Note that the surface smoothness can be measured with an atomic force microscope.

Furthermore, the substrate 1 has preferably high rigidity in order to prevent deformation due to film stress of a film (such as the multilayer reflective film 2) formed on the substrate 1. In particular, the substrate 1 preferably has a high Young's modulus of 65 GPa or more.

<<Multilayer Reflective Film>>

The multilayer reflective film 2 imparts a function to reflect EUV light in reflective masks 200, 400, and 600 (which may be simply referred to as “reflective mask 200”), and has a multilayer film configuration in which layers each including, as a main component, an element having a different refractive index are periodically layered.

Generally, as the multilayer reflective film 2, there is used a multilayer film in which a thin film (high refractive index layer) of a light element that is a high refractive index material or a compound of the light element and a thin film (low refractive index layer) of a heavy element that is a low refractive index material or a compound of the heavy element are alternately layered for about 40 to 60 periods. The multilayer film may be formed by counting, as one period, a stack of a high refractive index layer and a low refractive index layer in which the high refractive index layer and the low refractive index layer are layered in this order from the substrate 1 and then by building up the stack for a plurality of periods. Additionally, the multilayer film may be formed by counting, as one period, a stack of a low refractive index layer and a high refractive index layer in which the low refractive index layer and the high refractive index layer are layered in this order from the substrate 1 and by building up the stack for a plurality of periods. Note that a layer of the outermost surface of the multilayer reflective film 2, that is, a surface layer of the multilayer reflective film 2 on a side opposite to the substrate 1 is preferably a high refractive index layer. In a case where in the multilayer film described above, a stack of a high refractive index layer and a low refractive index layer in which the high refractive index layer and the low refractive index layer are layered in this order from the substrate 1 is counted as one period and the stack is built up for a plurality of periods, the uppermost layer is a low refractive index layer. In this case, if the low refractive index layer constitutes the outermost surface of the multilayer reflective film 2, the low refractive index layer is easily oxidized and the reflectance of the reflective mask 200 is reduced. Thus, it is preferable to further form a high refractive index layer on the low refractive index layer that is the uppermost layer to form the multilayer reflective film 2. Meanwhile, in a case where in the multilayer film described above, a stack of a low refractive index layer and a high refractive index layer in which the low refractive index layer and the high refractive index layer are layered in this order from the substrate 1 is counted as one period and the stack is built up for a plurality of periods, the uppermost layer is a high refractive index layer and thus the stack may be as it is.

In the present embodiment, a layer including silicon (Si) is employed as the high refractive index layer. As a material including Si, a Si compound including boron (B), carbon (C), nitrogen (N), and oxygen (O) in Si may be used in addition to Si alone. By using the layer containing Si as the high refractive index layer, the reflective mask 200 for EUV lithography having an excellent EUV light reflectance can be obtained. In addition, in the present embodiment, a glass substrate is preferably used as the substrate 1. Si also has excellent adhesion to the glass substrate. In addition, as the low refractive index layer, a metal alone selected from molybdenum (Mo), ruthenium (Ru), rhodium (Rh), and platinum (Pt), or an alloy thereof is used. For example, as the multilayer reflective film 2 for EUV light having a wavelength of 13 nm to 14 nm, a Mo/Si periodic film stack in which a Mo film and a Si film are alternately layered for about 40 to 60 periods is preferably used. Note that a high refractive index layer that is the uppermost layer of the multilayer reflective film 2 may be formed using silicon (Si), and a silicon oxide layer containing silicon and oxygen may be formed between the uppermost layer (Si) and the Ru-based protective film 3. Thus, mask cleaning resistance can be improved.

The reflectance of such a multilayer reflective film 2 alone is usually 65% or more, and an upper limit is usually 73%. Note that the thickness and period of each constituent layer of the multilayer reflective film 2 are appropriately selected according to an exposure wavelength and are selected so as to satisfy the Bragg reflection law. In the multilayer reflective film 2, there are a plurality of high refractive index layers and a plurality of low refractive index layers. The thickness does not need to be the same between high refractive index layers and between low refractive index layers. Additionally, the film thickness of the Si layer that is the outermost surface of the multilayer reflective film 2 can be adjusted within a range that does not lower the reflectance. The film thickness of the Si (high refractive index layer) of the outermost surface can be 3 nm to 10 nm.

A method of forming the multilayer reflective film 2 is publicly known in this technical field. For example, the multilayer reflective film 2 can be formed by forming a film of each layer in the multilayer reflective film 2 by an ion beam sputtering method. In the case of the above-mentioned Mo/Si periodic multilayer film, for example, a Si film having a thickness of about 4 nm is first formed on the substrate 1 using a Si target, for example, by the ion beam sputtering method. Then, a Mo film having a thickness of about 3 nm is formed using a Mo target. This formation is counted as one period and the Si film and the Mo film are stacked for 40 to 60 periods to form the multilayer reflective film 2 (the outermost layer is the Si layer). Additionally, when the multilayer reflective film 2 is formed, the multilayer reflective film 2 is preferably formed by supplying krypton (Kr) ion particles from an ion source and performing ion beam sputtering.

<<Protective Film>>

The reflective mask blank 100 of an embodiment of the present disclosure preferably has the protective film 3 between the multilayer reflective film 2 and the absorber film 4.

The protective film 3 is formed on the multilayer reflective film 2 in order to protect the multilayer reflective film 2 from dry etching and cleaning in a step of manufacturing the reflective mask 200 to be described later. Additionally, the protective film 3 also serves to protect the multilayer reflective film 2 when a black defect of the absorber pattern 4a is repaired using an electron beam (EB). Here, FIG. 1 shows a case where the protective film 3 is one layer, but the protective film 3 can include a stack of three or more layers. For example, the lowermost layer and the uppermost layer may be layers containing the substance containing Ru, and the protective film 3 may be one in which a metal or alloy other than Ru is interposed between the lowermost layer and the uppermost layer. A material of the protective film 3 includes, for example, a material including ruthenium as a main component. That is, the material of the protective film 3 may be a Ru metal alone or a Ru alloy containing Ru and at least one kind of a metal selected from titanium (Ti), niobium (Nb), molybdenum (Mo), zirconium (Zr), yttrium (Y), boron (B), lanthanum (La), cobalt (Co), rhenium (Re), and the like, and the material may contain nitrogen. Such a protective film 3 is effective particularly in a case where the absorber film 4 is made of an amorphous metal material of a Sn—X alloy and the absorber film 4 is patterned by dry etching with a chlorine-based gas (Cl-based gas). The protective film 3 is preferably formed of a material having a high etching selective ratio of the absorber film 4 to the protective film 3 in dry etching using a chlorine-based gas (etching rate of the absorber film 4/etching rate of the protective film 3) that is 1.5 or more, and preferably 3 or more.

The Ru content of this Ru alloy is 50 atomic % or more and less than 100 atomic %, preferably 80 atomic % or more and less than 100 atomic %, and more preferably 95 atomic % or more and less than 100 atomic %. In particular, in a case where the Ru content of the Ru alloy is 95 atomic % or more and less than 100 atomic %, the EUV light reflectance can be secured sufficiently while the diffusion of the element (silicon) constituting the multilayer reflective film 2 to the protective film 3 is suppressed. Furthermore, this protective film 3 can have mask cleaning resistance, an etching stopper function when the absorber film 4 is etched, and a function as the protective film 3 for preventing the multilayer reflective film 2 from changing over time.

In EUV lithography, since there are few substances that are transparent to exposure light, it is not technically easy to achieve an EUV pellicle that prevents foreign matters from adhering to a mask pattern surface. For this reason, pellicle-less operation without using a pellicle has been the mainstream. Additionally, in the case of EUV lithography, exposure contamination such as carbon film deposition on a mask or an oxide film growth due to EUV exposure occurs. Thus, it is necessary to frequently clean and remove foreign matters and contamination on the EUV reflective mask 200 at a stage where the mask is used for manufacturing a semiconductor device. For this reason, the EUV reflective mask 200 is required to have extraordinary mask cleaning resistance as compared with a transmissive mask for optical lithography. Using the Ru-based protective film 3 containing Ti provides particularly high cleaning resistance to cleaning liquids such as sulfuric acid, sulfuric acid peroxide (SPM), ammonia, ammonia peroxide (APM), hydroxyl (OH) radical cleaning water, and ozone water having a concentration of 10 ppm or less, thereby satisfying the requirement for mask cleaning resistance.

The thickness of the protective film 3 containing such Ru or an alloy thereof is not particularly limited as long as it can function as the protective film 3. The thickness of the protective film 3 is preferably 1.0 nm to 8.0 nm, and more preferably 1.5 nm to 6.0 nm from the viewpoint of the reflectance of EUV light.

As a method of forming the protective film 3, it is possible to adopt a film forming method similar to a publicly known one without any particular limitation. Specific examples include a sputtering method and an ion beam sputtering method.

<<Absorber Film>>

The reflective mask blank 100 of the present embodiment has a multilayer reflective film 2 and an absorber film 4 provided in this order on a substrate 1. The material of the absorber film 4 of the present embodiment includes an amorphous metal, and the amorphous metal includes tin (Sn) and a predetermined element. The film thickness of the absorber film 4 of the present embodiment is 55 nm or less.

Specifically, in the reflective mask blank 100 of the present embodiment, the absorber film 4 that absorbs EUV light is formed on the multilayer reflective film 2 or on the protective film 3. In order to reduce the shadowing effect of the reflective mask 200, it is necessary to reduce the film thickness of the absorber film 4. Since the absorber film 4 has a function of absorbing EUV light, in order to make the absorber film 4 thinner, the material of the absorber film 4 needs to be highly capable of absorbing EUV light. The amorphous metal included in the material of the absorber film 4 of the present embodiment contains tin (Sn), and thus has a high extinction coefficient. The amorphous metal included in the material of the absorber film 4 contains tin (Sn), and resultingly the extinction coefficient k of the absorber film 4 can be 0.035 or more, and preferably 0.045 or more. Therefore, the absorber film 4 of the present embodiment provides a low reflectance of EUV light even when the film thickness thereof is as thin as 55 nm or less. Using the reflective mask blank 100 of the present embodiment makes it possible to reduce the film thickness of the absorber film 4, thereby further reducing the shadowing effect of the reflective mask 200.

In order to manufacture the reflective mask 200, the absorber film 4 of the reflective mask blank 100 needs to be made of a material that can be processed by dry etching. The absorber film 4 of the reflective mask blank 100 of the present embodiment is made of a material including an amorphous metal that contains the element of tin (Sn), and therefore it is made possible to improve the pattern shape and the processing characteristics when the absorber film 4 is dry-etched to form the absorber pattern 4a.

Examples of the amorphous metal included in the material of the absorber film 4 include a material obtained by adding at least one or more elements (X) selected from tantalum (Ta), chromium (Cr), cobalt (Co), nickel (Ni), antimony (Sb), platinum (Pt), iridium (Ir), iron (Fe), gold (Au), aluminum (Al), copper (Cu), zinc (Zn), and silver (Ag) to the element of tin (Sn). An alloy (amorphous metal) containing tin (Sn) and any of these elements (X) may be herein referred to as “Sn—X alloy”. In order to improve processing characteristics of the absorber film 4, the absorber film 4 is preferably made of an amorphous metal being the above-mentioned Sn—X alloy.

Since tin (Sn) has low thermal stability with a melting point of 231° C., in a case where the material of the absorber film is made of tin (Sn) only, there is a concern about heat resistance during manufacture of the reflective mask 200 and during exposure to EUV. In addition, an absorber film made of tin (Sn) only may pose a problem of low cleaning resistance. The absorber film 4 of the present embodiment can overcome such problems by alloying tin (Sn) with a predetermined element (X) mentioned above.

The content of tin (Sn) in the absorber film 4 of the present embodiment is preferably 10 atomic % or more and 90 atomic % or less, more preferably 20 atomic % or more and 85 atomic % or less, and still more preferably 30 atomic % or more and 75 atomic % or less. When the content of tin (Sn) is low, the effect provided by blending tin (Sn) having a high extinction coefficient k may be reduced. In addition, when the content of tin (Sn) is high, the problem of a low melting point of tin (Sn) may arise. Therefore, when the content of tin (Sn) in the absorber film 4 is within the above-described range, it is made possible to obtain an absorber film that does not pose a problem caused by the fact that tin (Sn) has a low melting point without reducing the effect provided by blending tin (Sn) having a high extinction coefficient k.

The amorphous metal included in the material of the absorber film 4 of the present embodiment preferably contains tin (Sn) and at least one or more elements selected from tantalum (Ta), chromium (Cr), platinum (Pt), iridium (Ir), iron (Fe), gold (Au), aluminum (Al), and zinc (Zn). In a case where any of Ta, Cr, Pt, Ir, Fe, Au, Al, and Zn, each of which individually has an extinction coefficient of about 0.03 to 0.06, is added as an additive element (X) to the absorber film 4, the content thereof is preferably 60 atomic % or less, more preferably 50 atomic % or less, and still more preferably 40 atomic % or less. The extinction coefficient k of the absorber film 4 for EUV light having a wavelength of 13.5 nm needs to be adjusted so as not to be less than 0.035. When the content of the above-described additive element (X) in the absorber film 4 is in the above-described range, the extinction coefficient k of the absorber film 4 for EUV light having a wavelength of 13.5 nm can be adjusted not to be less than 0.035.

The amorphous metal included in the material of the absorber film 4 of the present embodiment preferably contains tin (Sn) and at least one or more elements selected from cobalt (Co), nickel (Ni), antimony (Sb), copper (Cu), and silver (Ag). Each of Co, Ni, Sb, Cu, and Ag individually has an extinction coefficient k of 0.06 or more. Therefore, in a case where at least one or more elements selected from Co, Ni, Sb, Cu, and Ag are added as an additive element (X) to the amorphous metal included in the material of the absorber film 4, the extinction coefficient k of the absorber film 4 is easily adjusted to 0.035 or more. In addition, it is also possible to adjust the extinction coefficient k of the absorber film 4 to 0.045 or more by adding the additive element (X). Furthermore, it is also possible to make the extinction coefficient k of the absorber film 4 0.055 or more by adding the additive element (X). Therefore, the content of the additive element (X) can be increased in consideration of processing characteristics.

In particular, Ta and Cr can be preferably used as the additive element (X) because Ta and Cr have good processing characteristics. The content of Ta or Cr in the amorphous metal included in the material of the absorber film 4 is, from the viewpoint of reducing the thickness of the absorber film 4, preferably 60 atomic % or less, more preferably 50 atomic % or less, still more preferably less than 40 atomic %, and still more preferably less than 25 atomic %. In addition, from the viewpoint of processing characteristics, the content of Ta or Cr in the amorphous metal is preferably more than 15 atomic %, and more preferably 20 atomic % or more. In a case where the additive element (X) of the Sn—X alloy is Ta, the composition ratio of Sn to Ta (Sn:Ta) is preferably 9:1 to 1:9, and more preferably 4:1 to 1:4. With the composition ratios of Sn to Ta being 2:1, 1:1, and 1:2, each sample was analyzed by the X-ray diffractometer (XRD) and cross-sectional TEM observation was performed, and Sn and Ta-derived peaks changed while the widths of the peaks became broad. This indicates that the Sn—Ta alloy had an amorphous structure. In addition, in a case where the additive element (X) of the Sn—X alloy is Cr, the composition ratio of Sn to Cr (Sn:Cr) is preferably 9:1 to 1:9, and more preferably 4:1 to 1:4. In a case where the additive element (X) of the Sn—X alloy is Ni, the composition ratio of Sn to Ni (Sn:Ni) is preferably 9:1 to 1:9, and more preferably 4:1 to 1:4. In addition, in a case where the additive element (X) of the Sn—X alloy is Co, the composition ratio of Sn to Co (Sn:Co) is preferably 9:1 to 1:9, and more preferably 4:1 to 1:4.

Additionally, in addition to the above additive element (X), the Sn—X alloy (amorphous metal) may include other elements such as nitrogen (N), oxygen (O), carbon (C), or boron (B) to the extent that the refractive index and extinction coefficient are not significantly affected. It is preferable to use a Sn—X alloy containing nitrogen (N) as the absorber film 4 because the etching rate can be increased. In addition, resistance to oxidation is improved by containing nitrogen (N), and thus stability over time can be improved and oxidation after photomask processing can also be prevented. The content of nitrogen (N) in the Sn—X alloy (amorphous metal) is preferably 2 atomic % or more, and more preferably 5 atomic % or more. In addition, the content of nitrogen (N) in the Sn—X alloy is preferably 55 atomic % or less, and more preferably 50 atomic % or less.

The absorber film 4 may be a single layer film or a multilayer film including two or more films. In the case of a single layer film, the number of steps at the time of manufacturing the mask blank can be reduced and thus production efficiency is increased.

In a case where the absorber film 4 is a multilayer film, the absorber film 4 may have, for example, a two-layer structure including a lower layer film and an upper layer film layered from the substrate 1 side. The lower layer film can be formed of an amorphous metal of a Sn—X alloy having a high extinction coefficient for EUV light. The upper layer film can be formed of a material obtained by adding oxygen (O) to the amorphous metal of a Sn—X alloy. It is preferable that the optical constant and the film thickness of the upper layer film are appropriately set so that the upper layer film serves as an antireflection film when a mask pattern is inspected with DUV light, for example. The upper layer film has a function of an antireflection film, thereby improving the inspection sensitivity when a mask pattern is inspected with light. In this manner, by making the absorber film 4 a multilayer film, various functions can be added. In a case where the absorber film 4 has a phase shift function, the absorber film 4 is formed to be a multilayer film, whereby a range of adjustment on the optical surface expands and it becomes easy to obtain desired reflectance. In a case where the absorber film 4 is a multilayer film having two or more layers, one layer included in the multilayer film may be an amorphous metal of a Sn—X alloy.

The absorber film 4 made of such amorphous metal can be formed by a publicly known method such as a direct current (DC) sputtering method or a magnetron sputtering method such as a radio frequency (RF) sputtering method. As the target, a metal target of a Sn—X alloy may be used, or co-sputtering employing a Sn target and an additive element (X) target may be used.

In the case of the absorber film 4 intended to absorb EUV light, the film thickness thereof is set so that the reflectance of EUV light to the absorber film 4 is 2% or less, and preferably 1% or less. Additionally, in order to reduce the shadowing effect, the film thickness of the absorber film 4 is required to be 55 nm or less, preferably 50 nm or less, and more preferably 45 nm or less.

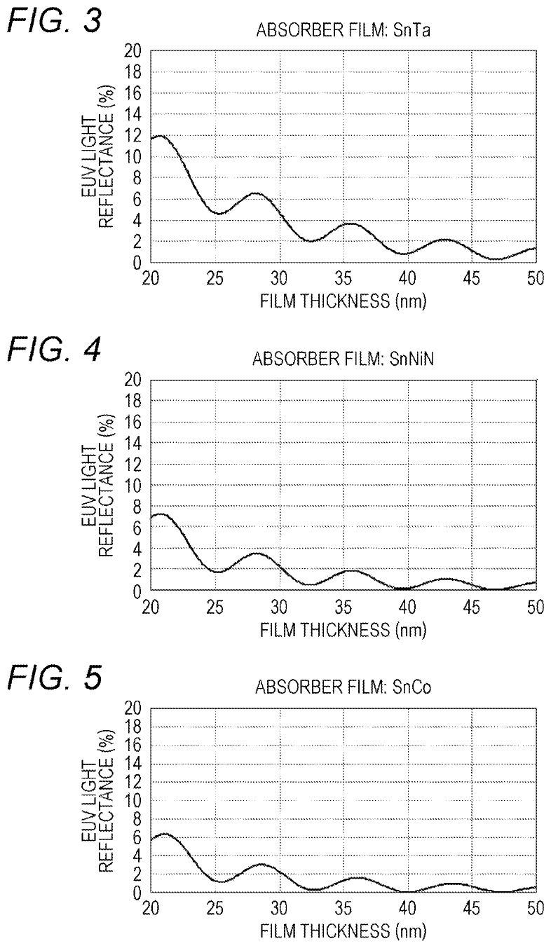

In order to obtain a relationship between the film thickness of the absorber film 4 and the reflectance (%) of EUV light on a surface of the absorber film 4, simulations as shown in FIGS. 3 to 5 were conducted. The structure used for the simulations shown in FIGS. 3 to 5 is a structure in which the multilayer reflective film 2 of Mo/Si periodic films and the protective film 3 (film thickness: 3.5 nm) made of ruthenium as a material are formed on the substrate 1, and the absorber film 4 is further formed. The multilayer reflective film 2 of the Mo-Si periodic films had a structure in which the film thickness of the Si layer is 4.2 nm and the film thickness of the Mo layer is 2.8 nm, the layers are built up on the substrate 1 for 40 periods where a single Si layer and a single Mo layer are counted as one period, and the Si layer having a thickness of 4.0 nm is disposed as the uppermost layer.

As shown in FIG. 3, in a case where the absorber film 4 is formed of a SnTa alloy film (Sn:Ta=50:50 in terms of atomic ratio), a film thickness in a range from 32 nm to 55 nm can be selected for the reflectance of 2% or less for 13.5 nm EUV light. In addition, a film thickness in a range from 39 nm to 49 nm can be selected for the reflectance of 1% or less for 13.5 nm EUV light. For example, setting the film thickness to 39 nm can provide the reflectance of 1% for 13.5 nm EUV light.

Additionally, as shown in FIG. 4, in a case where the absorber film 4 is formed of a SnNiN alloy film (Sn:Ni:N=45:45:10 in terms of atomic ratio), a film thickness in a range from 24 nm to 55 nm can be selected for the reflectance of 2% or less for 13.5 nm EUV light. In addition, a film thickness in a range from 31 nm to 50 nm can be selected for the reflectance of 1% or less for 13.5 nm EUV light. For example, setting the film thickness to 40 nm can provide the reflectance of 0.1% for 13.5 nm EUV light.

Additionally, as shown in FIG. 5, in a case where the absorber film 4 is formed of a SnCo alloy film (Sn:Co=50:50 in terms of atomic ratio), a film thickness in a range from 24 nm to 55 nm can be selected for the reflectance of 2% or less for 13.5 nm EUV light. In addition, a film thickness in a range from 31 nm to 50 nm can be selected for the reflectance of 1% or less for 13.5 nm EUV light. For example, setting the film thickness to 40 nm can provide the reflectance of 0.01% for 13.5 nm EUV light.

The absorber film 4 may be an absorber film 4 intended to absorb EUV light as the binary-type reflective mask blank 100, or may be an absorber film 4 having a phase shift function in consideration of a phase difference of EUV light as the phase shift-type reflective mask blank 100.

In the case of the absorber film 4 having a phase shift function, in a portion where the absorber film 4 is formed, part of light is reflected at a level that does not adversely affect pattern transfer while EUV light is absorbed and reduced. The light reflected from the portion where the absorber film 4 is formed forms a desired phase difference with the reflected light from a field portion reflected from the multilayer reflective film 2 via the protective film 3. The absorber film 4 is formed so that the phase difference between the reflected light from the absorber film 4 and the reflected light from the multilayer reflective film 2 is 160° to 200°. Beams of the light having a reversed phase difference in the neighborhood of 180° interfere with each other at a pattern edge portion, whereby the image contrast of a projected optical image is improved. As the image contrast is improved, resolution is increased and various exposure-related margins such as an exposure margin and a focus margin increase. In general, a measure of the reflectance for sufficiently obtaining this phase shift effect is 1% or more in terms of absolute reflectance and a reflection ratio with respect to the multilayer reflective film 2 (with the protective film 3) is 2% or more, although the measure depends on pattern and exposure conditions.

In addition, as the etching gas for the absorber film 4, it is possible to use a chlorine-based gas such as Cl₂, SiCl₄, CHCl₃, CCl₄, and BCl₃, a mixed gas containing at least two types of gases selected from these chlorine-based gases, a mixed gas containing a chlorine-based gas and He at a predetermined ratio, or a mixed gas containing a chlorine-based gas and Ar at a predetermined ratio. As other etching gases, it is possible to use one selected from a fluorine-based gas such as CF₄, CHF₃, C₂F₆, C₃F₆, C₄F₆, C₄F₈, CH₂F₂, CH₃F, C₃F₈, SF₆, and F₂, a mixed gas including a fluorine-based gas and O₂ at a predetermined ratio, and the like. Furthermore, as the etching gas, it is possible to use a mixed gas or the like containing any of these gases and an oxygen gas.

For example, in a case where any of Ta, Cr, Co, Ni, Sb, Fe, Au, and Al is used as the additive element (X), etching is preferably performed with a chlorine-based gas.

In addition, in the case of the absorber film 4 having a two-layer structure, an etching gas may be different between an upper layer film and a lower layer film. For example, as the etching gas for the upper layer film, it is possible to use one selected from a fluorine-based gas such as CF₄, CHF₃, C₂F₆, C₃F₆, C₄F₆, C₄F₈, CH₂F₂, CH₃F, C₃F₈, SF₆, and F₂, a mixed gas containing a fluorine-based gas and O₂ at a predetermined ratio, and the like. In addition, as the etching gas for the lower layer film, it is possible to use one selected from a chlorine-based gas such as Cl₂, SiCl₄, CHCl₃, CCl₄, and BCl₃, a mixed gas containing at least two types of gases selected from these chlorine-based gases, a mixed gas containing a chlorine-based gas and He at a predetermined ratio, and a mixed gas containing a chlorine-based gas and Ar at a predetermined ratio. Here, an etching gas containing oxygen in the final stage of etching causes surface roughness of the Ru-based protective film 3. For this reason, it is preferable to use an etching gas that does not include oxygen in an over-etching stage in which the Ru-based protective film 3 is exposed to etching. Additionally, in the case of the absorber film 4 having an oxide layer formed on a surface thereof, it is preferable to remove the oxide layer using a first etching gas and dry-etch the remaining absorber film 4 using a second etching gas. A first etching gas may be a chlorine-based gas including BCl₃ gas, and a second etching gas may be a chlorine-based gas including Cl₂ gas or the like that is different from the first etching gas. As a result, the oxide layer can be easily removed, and the etching time of the absorber film 4 can be shortened.

According to the reflective mask blank 100 of the present embodiment (the reflective mask 200 manufactured with this reflective mask blank), the film thickness of the absorber film 4 is reduced so that the shadowing effect can be suppressed, and a fine and highly accurate absorber pattern 4a can be formed in a stable cross-sectional shape with small sidewall roughness. In addition, alloying with various metals not only significantly increases the melting point of the tin (Sn) alloy but also improves the cleaning resistance of the absorber film 4 (absorber pattern 4a). Thus, the reflective mask 200 manufactured by using the reflective mask blank 100 having this structure can form the absorber pattern 4a itself finely and highly accurately on the mask and at the same time prevent a decrease in the accuracy due to shadowing during transfer. In addition, by performing EUV lithography using this reflective mask 200, it becomes possible to provide a method of manufacturing a fine and highly accurate semiconductor device.

<<Etching Mask Film>>

As shown in FIG. 6, the reflective mask blank 300 of the present embodiment preferably has the etching mask film 6 on the absorber film 4. In this case, the etching mask film 6 preferably includes a material including chromium (Cr) or a material including silicon (Si).

Providing the etching mask film 6 makes it possible to reduce the film thickness of the resist film 11 when the absorber pattern 4a is formed and to accurately form the transfer pattern on the absorber film 4. As a material of the etching mask film 6, a material having a high etching selective ratio of the absorber film 4 to the etching mask film 6 is used. Here, the expression of “an etching selective ratio of B to A” means a ratio of an etching rate of A that is a layer that is not desired to be etched (layer to serve as a mask) to an etching rate of B that is a layer that is desired to be etched. Specifically, “an etching selective ratio of B to A” is specified by the formula of “an etching selective ratio of B to A=an etching rate of B/an etching rate of A”. Additionally, the expression of “high selective ratio” means that a value of the selective ratio defined above is large as compared with that of an object for comparison. The etching selective ratio of the absorber film 4 to the etching mask film 6 is preferably 1.5 or more, and more preferably 3 or more.

Examples of the material of the etching mask film 6 having a high etching selective ratio of the absorber film 4 to the etching mask film 6 include a chromium material and a chromium compound material. In this case, the absorber film 4 can be etched by a fluorine-based gas or a chlorine-based gas. Examples of the chromium compound include a material including Cr and at least one element selected from N, O, C, B, and H. Examples of the chromium compound include CrN, CrC, CrO, CrON, CrOC, CrCN, CrCON, CrBN, CrBC, CrBO, CrBC, CrBON, CrBCN, and CrBOCN. In order to increase the etching selective ratio with a chlorine-based gas, it is preferable that the etching mask film 6 is made of a material substantially including no oxygen. Examples of the chromium compound substantially including no oxygen include CrN, CrC, CrCN, CrBN, CrBC, and CrBCN. The Cr content in the chromium compound for the etching mask film 6 is preferably 50 atomic % or more and less than 100 atomic %, and more preferably 80 atomic % or more and less than 100 atomic %. Additionally, the expression of “substantially including no oxygen” corresponds to a chromium compound having an oxygen content of 10 atomic % or less, and preferably 5 atomic % or less. Note that the material can contain a metal other than chromium to the extent that the effects of an embodiment of the present disclosure can be obtained.

In addition, in a case where the absorber film 4 is etched with a chlorine-based gas substantially containing no oxygen, a silicon material or a silicon compound material can be used as the etching mask film 6. Examples of the silicon compound include a material containing Si and at least one element selected from N, O, C and H, and a material such as metal silicon (metal silicide) and a metal silicon compound (metal silicide compound) containing metal in silicon or a silicon compound. Specific examples of a material including silicon include SiO, SiN, SiON, SiC, SiCO, SiCN, SiCON, MoSi, MoSiO, MoSiN, and MoSiON. Note that the material can contain a metalloid or metal other than silicon to the extent that the effects of an embodiment of the present disclosure can be obtained.

In order that the etching selective ratio of the absorber film 4 to the etching mask film 6 in dry etching with a chlorine-based gas is 1.5 or more, content of the additive element (X) in the absorber film 4 is preferably 20 atomic % or more.

The film thickness of the etching mask film 6 is desirably 3 nm or more from the viewpoint of obtaining a function as an etching mask for accurately forming the transfer pattern on the absorber film 4. Additionally, the film thickness of the etching mask film 6 is desirably 15 nm or less, and more preferably 10 nm or less from the viewpoint of reducing the film thickness of the resist film 11.

<<Etching Stopper Film>>

As shown in FIG. 8, the reflective mask blank 500 of the present embodiment may have the etching stopper film 7 formed between the protective film 3 and the absorber film 4. As a material of the etching stopper film 7, it is preferable to use a material having a high etching selective ratio of the absorber film 4 to the etching stopper film 7 in dry etching using a chlorine-based gas (etching rate of the absorber film 4/etching rate of the etching stopper film 7). Examples of such a material include materials of chromium and chromium compounds. Examples of the chromium compound include a material including Cr and at least one element selected from N, O, C, B, and H. Examples of the chromium compound include CrN, CrC, CrO, CrON, CrOC, CrCN, CrCON, CrBN, CrBC, CrBO, CrBC, CrBON, CrBCN, and CrBOCN. In order to increase the etching selective ratio with a chlorine-based gas, it is preferable to use a material substantially including no oxygen. Examples of the chromium compound substantially including no oxygen include CrN, CrC, CrCN, CrBN, CrBC, and CrBCN. The Cr content of the chromium compound is preferably 50 atomic % or more and less than 100 atomic %, and more preferably 80 atomic % or more and less than 100 atomic %. Note that the material of the etching stopper film 7 can contain a metal other than chromium to the extent that the effects of an embodiment of the present disclosure can be obtained.

Additionally, when the absorber film 4 is etched with a chlorine-based gas, a silicon material or a silicon compound material can be used for the etching stopper film 7. Examples of the silicon compound include materials such as a material including Si and at least one element selected from N, O, C, and H, metallic silicon including a metal in silicon or a silicon compound (metal silicide), and a metal silicon compound (metal silicide compound). Specific examples of a material including silicon include SiO, SiN, SiON, SiC, SiCO, SiCN, SiCON, MoSi, MoSiO, MoSiN, and MoSiON. Note that the material can contain a metalloid or metal other than silicon to the extent that the effects of an embodiment of the present disclosure can be obtained.

Additionally, the etching stopper film 7 is preferably formed of the same material as the material of the above-described etching mask film 6. As a result, the above-described etching mask film 6 can be removed at the same time when the etching stopper film 7 is patterned. Additionally, the etching stopper film 7 and the etching mask film 6 may be formed of a chromium compound or a silicon compound, and the composition ratios of the etching stopper film 7 and the etching mask film 6 may be different from each other.

The film thickness of the etching stopper film 7 is preferably 2 nm or more from the viewpoint of preventing optical characteristics from changing due to damaging to the protective film 3 when the absorber film 4 is etched. Additionally, the film thickness of the etching stopper film 7 is preferably 7 nm or less, and more preferably 5 nm or less from the viewpoint of reducing the total film thickness of the absorber film 4 and the etching stopper film 7, that is, the viewpoint of reducing the height of a pattern including the absorber pattern 4a and the etching stopper pattern 7a.

Additionally, in a case where the etching stopper film 7 and the etching mask film 6 are etched at the same time, the film thickness of the etching stopper film 7 is preferably the same as or thinner than the film thickness of the etching mask film 6. Furthermore, in a case where (film thickness of the etching stopper film 7)≤(film thickness of the etching mask film 6) holds, the relationship of (etching rate of the etching stopper film 7)≤(etching rate of the etching mask film 6) is preferably satisfied.

<<Conductive Back Film>>

The conductive back film 5 for an electrostatic chuck is generally formed on the side of the second main surface (back surface) of the substrate 1 (side opposite to a forming face of the multilayer reflective film 2). An electrical characteristic (sheet resistance) required of the conductive back film 5 for an electrostatic chuck is usually 100 Ω/□ (Ω/square) or less. By a method of forming the conductive back film 5, it is possible to form the conductive back film 5 using, for example, a magnetron sputtering method or an ion beam sputtering method using a target of a metal such as chromium, tantalum, and the like or an alloy thereof.

A material including chromium (Cr) for the conductive back film 5 is preferably a Cr compound containing Cr and at least one selected from boron, nitrogen, oxygen, and carbon. Examples of the Cr compound include CrN, CrON, CrCN, CrCON, CrBN, CrBON, CrBCN, and CrBOCN.

As a material including tantalum (Ta) for the conductive back film 5, it is preferable to use Ta (tantalum), an alloy containing Ta, or a Ta compound containing either of Ta or the alloy containing Ta and at least one from boron, nitrogen, oxygen, and carbon. Examples of the Ta compound include TaB, TaN, TaO, TaON, TaCON, TaBN, TaBO, TaBON, TaBCON, TaHf, TaHfO, TaHfN, TaHfON, TaHfCON, TaSi, TaSiO, TaSiN, TaSiON, and TaSiCON.

As a material including tantalum (Ta) or chromium (Cr), an amount of nitrogen (N) present in the surface layer thereof is preferably small. Specifically, it is preferable that nitrogen content in the surface layer of the conductive back film 5 of the material including tantalum (Ta) or chromium (Cr) is less than 5 atomic %, and it is more preferable that the surface layer substantially contains no nitrogen. This is because in the conductive back film 5 of the material including tantalum (Ta) or chromium (Cr), the lower the nitrogen content in the surface layer is, the higher wear resistance is.

The conductive back film 5 preferably includes a material including tantalum and boron. The conductive back film 5 includes the material including tantalum and boron, whereby a conductive film 23 having wear resistance and chemical resistance can be obtained. In a case where the conductive back film 5 includes tantalum (Ta) and boron (B), B content is preferably 5 to 30 atomic %. The ratio of Ta to B (Ta:B) in a sputtering target used for forming the conductive back film 5 is preferably from 95:5 to 70:30.

The thickness of the conductive back film 5 is not particularly limited as long as a function as being for an electrostatic chuck is fulfilled. The thickness of the conductive back film 5 is usually 10 nm to 200 nm. In addition, the conductive back film 5 further includes a function of stress adjustment on the side of the second main surface of the mask blank 100. Therefore, the film thickness of the conductive back film 5 is adjusted so that the flat reflective mask blank 100 can be obtained in balance with the stress from various films formed on the side of the first main surface.

<Reflective Mask and Method of Manufacturing the Same>

The reflective mask 200 of the present embodiment includes the absorber pattern 4a in which the absorber film 4 in the above-described reflective mask blank 100 is patterned. The absorber pattern 4a can be formed by patterning the absorber film 4 of the above-described reflective mask blank 100 by dry etching with a chlorine-based gas.

The reflective mask 200 can be manufactured by using the reflective mask blank 100 of the present embodiment. FIG. 2 illustrates a method of manufacturing the reflective mask 200 shown in FIG. 2(d) by using the reflective mask blank 100 shown in FIG. 1.

In the method of manufacturing the reflective mask 200 of the present embodiment as illustrated in FIG. 2, the reflective mask blank 100 is prepared, and a resist film 11 is formed on the absorber film 4 on a first main surface of the reflective mask blank 100 (FIG. 2(a)). However, if the resist film 11 is provided as the reflective mask blank 100, this step is unnecessary. A desired pattern is drawn (exposed) on this resist film 11, and is further developed and rinsed to form a predetermined resist pattern 11a (FIG. 2(b)).

In the manufacturing method of the present embodiment, the resist pattern 11a is used as a mask, and the absorber pattern 4a is formed by etching the absorber film 4 (FIG. 2(c)). The absorber pattern 4a is formed by removing the resist pattern 11a by ashing or resist stripper liquid (FIG. 2(d)). Finally, wet cleaning is performed using an acidic or alkaline aqueous solution.

Here, as the etching gas for the absorber film 4, the above-described chlorine-based gas, fluorine-based gas, or the like is used depending on the material of the absorber film 4. It is preferable that the etching gas substantially includes no oxygen in etching of the absorber film 4. This is because surface roughness does not occur on the Ru-based protective film 3 when the etching gas substantially includes no oxygen. The gas substantially including no oxygen corresponds to a gas having an oxygen content of 5 atomic % or less.

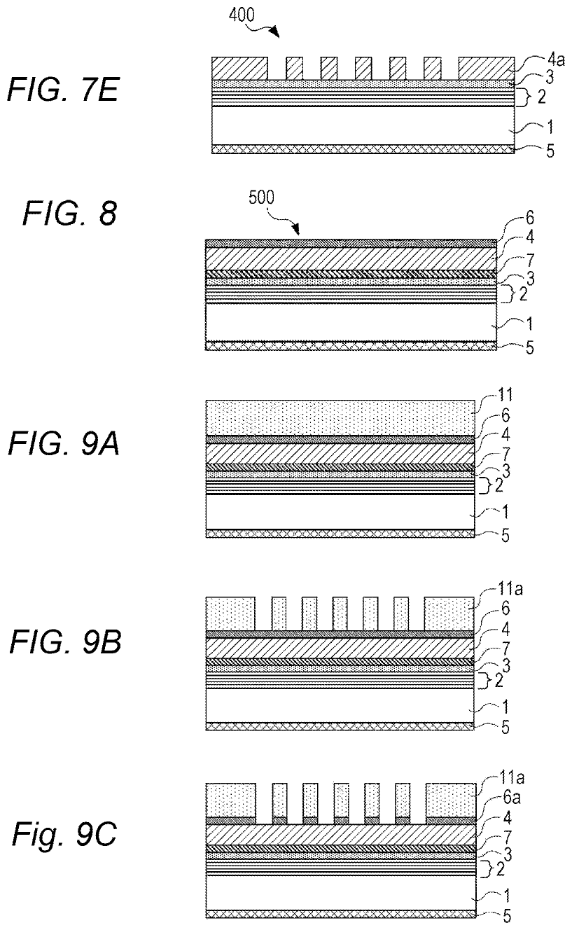

The reflective mask blank 300 illustrated in FIG. 6 includes the etching mask film 6. FIG. 7 illustrates a method of manufacturing the reflective mask 400 shown in FIG. 7(e) by using the reflective mask blank 300 shown in FIG. 6.

In the method of manufacturing the reflective mask 400 of the present embodiment as illustrated in FIG. 7, the reflective mask blank 300 is prepared, and a resist film 11 is formed on the etching mask film 6 on a first main surface of the reflective mask blank 300 (FIG. 7(a)). However, if the resist film 11 is provided as the reflective mask blank 300, this step is unnecessary. A desired pattern is drawn (exposed) on this resist film 11, and is further developed and rinsed to form a predetermined resist pattern 11a (FIG. 7(b)).

In the manufacturing method of the present embodiment, the resist pattern 11a is used as a mask, and the etching mask pattern 6a is formed by etching the etching mask film 6 (FIG. 7(c)).

The resist pattern 11a is peeled off by oxygen ashing or wet treatment with hot sulfuric acid or the like. Next, the etching mask pattern 6a is used as a mask, and the absorber pattern 4a is formed by etching the absorber film 4 (FIG. 7(d)). The etching mask pattern 6a is peeled off and removed by etching to obtain the reflective mask 400 on which the absorber pattern 4a is formed (FIG. 7(e)). Finally, wet cleaning is performed using an acidic or alkaline aqueous solution.

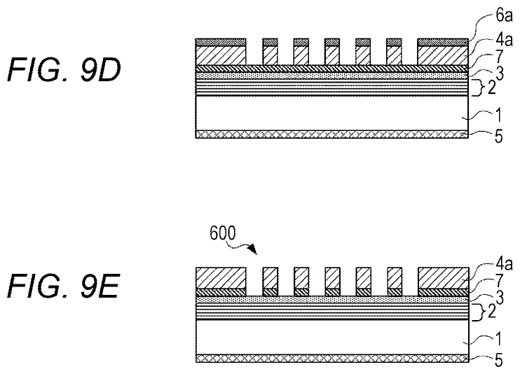

The reflective mask blank 500 illustrated in FIG. 8 includes the etching mask film 6 and the etching stopper film 7. FIG. 9 illustrates a method of manufacturing the reflective mask 600 shown in FIG. 9(e) by using the reflective mask blank 500 shown in FIG. 8.

In the method of manufacturing the reflective mask 600 of the present embodiment as illustrated in FIG. 9, the reflective mask blank 100 is prepared, and a resist film 11 is formed on the etching mask film 6 on a first main surface of the reflective mask blank 100 (FIG. 9(a)). However, if the resist film 11 is provided as the reflective mask blank 500, this step is unnecessary. A desired pattern is drawn (exposed) on this resist film 11, and is further developed and rinsed to form a predetermined resist pattern 11a (FIG. 9(b)).

In the manufacturing method of the present embodiment, the resist pattern 11a is used as a mask, and the etching mask pattern 6a is formed by etching the etching mask film 6 (FIG. 9(c)).

The resist pattern 11a is peeled off by oxygen ashing or wet treatment with hot sulfuric acid or the like. Next, the etching mask pattern 6a is used as a mask, and the absorber pattern 4a is formed by etching the absorber film 4 (FIG. 9(d)). The etching stopper film 7 is patterned and, at the same time, the etching mask pattern 6a is removed, whereby the reflective mask 600 on which the etching stopper pattern 7a and the absorber pattern 4a are formed is obtained (FIG. 9(e)). Finally, wet cleaning is performed using an acidic or alkaline aqueous solution.

Through the above steps, the reflective mask 200, 400, 600 having a fine and highly accurate pattern having a small shadowing effect and small wall roughness can be obtained.

<Method of Manufacturing Semiconductor Device>

A method of manufacturing a semiconductor device according to an embodiment of the present disclosure includes a step of setting the above-described reflective mask 200 in an exposure apparatus having an exposure light source that emits EUV light and transferring a transfer pattern to a resist film formed on a transfer-receiving substrate.

By performing EUV exposure using the above-described reflective mask 200 of the present embodiment, a desired transfer pattern based on an absorber pattern 4a on the reflective mask 200 can be formed on the semiconductor substrate while a decrease in accuracy of a transfer dimension due to a shadowing effect can be suppressed. In addition, since the absorber pattern 4a is a fine and highly accurate pattern with small sidewall roughness, a desired pattern can be formed on the semiconductor substrate with high dimensional accuracy. In addition to this lithography step, various steps such as etching of a film to be processed, formation of an insulating film and a conductive film, introduction of a dopant, or annealing are undergone, whereby it is possible to manufacture a semiconductor device on which a desired electronic circuit is formed.

More specifically, the EUV exposure apparatus includes a laser plasma light source that generates EUV light, an illumination optical system, a mask stage system, a reduction projection optical system, a wafer stage system, and vacuum equipment, and the like. The light source is provided with a debris trap function, a cut filter that cuts light having a long wavelength other than exposure light, equipment for vacuum differential pumping, and the like. The illumination optical system and the reduction projection optical system each include a reflection mirror. The reflective mask 200 for EUV exposure is electrostatically attracted by the conductive film formed on the second main surface of the reflective mask 200 and is mounted on the mask stage.

The light of the EUV light source is applied to the reflective mask 200 through the illumination optical system at an angle tilted by 6° to 8° with respect to a vertical plane of the reflective mask 200. Reflected light from the reflective mask 200 with respect to this incident light is reflected (regularly reflected) in a direction opposite to an incident direction and at the same angle as an incident angle, guided to a reflective projection system usually having a reduction ratio of ¼, and exposed on a resist on a wafer (semiconductor substrate) mounted on a wafer stage. During this time, at least a place through which EUV light passes is evacuated. Additionally, when this exposure is performed, mainstream exposure is scan exposure in which the mask stage and the wafer stage are synchronously scanned at a speed corresponding to the reduction ratio of the reduction projection optical system, and exposure is performed through a slit. Then, the resist film that has been subjected to the exposure is developed, whereby a resist pattern can be formed on the semiconductor substrate. In an embodiment of the present disclosure, the mask having the highly accurate absorber pattern 4a that is a thin film and has a small shadowing effect and small sidewall roughness is used. Therefore, the resist pattern formed on the semiconductor substrate is desired one with high dimensional accuracy. Then, etching or the like is performed using this resist pattern as a mask, whereby a predetermined wiring pattern can be formed, for example, on the semiconductor substrate. The semiconductor device is manufactured through such an exposure step, a step of processing a film to be processed, a step of forming an insulating film and a conductive film, a dopant introduction step, an annealing step, and other necessary steps.

### EXAMPLES

Hereinafter, Examples will be described with reference to the drawings. Note that in Examples, the same reference signs will be used for similar constituent elements, and the description thereof will be simplified or omitted.

### Example 1

As illustrated in FIG. 1, the reflective mask blank 100 of Example 1 includes the conductive back film 5, the substrate 1, the multilayer reflective film 2, the protective film 3, and the absorber film 4. The absorber film 4 is made of a material including a SnTa amorphous alloy. Then, as shown in FIG. 2(a), the resist film 11 is formed on the absorber film 4. FIGS. 2(a) to 2(d) are each a schematic cross-sectional diagram of a main part showing a step of manufacturing the reflective mask 200 from the reflective mask blank 100.

First, the reflective mask blank 100 of Example 1 will be described.

A SiO₂—TiO₂-based glass substrate that is a low thermal expansion glass substrate having 6025 size (approximately 152 mm×152 mm×6.35 mm) and having polished both main surfaces that are a first main surface and a second main surface was prepared as the substrate 1. The main surfaces were subjected to polishing including a rough polishing step, a precision polishing step, a local processing step, and a touch polishing step so that the main surfaces were flat and smooth.

Next, the conductive back film 5 including a CrN film was formed on the second main surface (a back surface) of the SiO₂—TiO₂-based glass substrate (the substrate 1) by a magnetron sputtering (a reactive sputtering) method under the following conditions.

Conditions for forming the conductive back film 5: a Cr target, a mixed gas atmosphere of Ar and N₂(Ar: 90%, N: 10%), and a film thickness of 20 nm.

Next, the multilayer reflective film 2 was formed on the main surface (first main surface) of the substrate 1 on a side opposite to a side on which the conductive back film 5 was formed. The multilayer reflective film 2 formed on the substrate 1 was a periodic multilayer reflective film including Mo and Si in order to make the multilayer reflective film 2 suitable for EUV light having a wavelength of 13.5 nm. The multilayer reflective film 2 was formed using a Mo target and a Si target and alternately layering a Mo layer and a Si layer on the substrate 1 by an ion beam sputtering method in an Ar gas atmosphere. First, a Si film was formed with a thickness of 4.2 nm, and then a Mo film was formed with a thickness of 2.8 nm. This formation was counted as one period, and the Si film and the Mo film were layered for 40 periods in a similar manner. Finally, a Si film was formed with a thickness of 4.0 nm to form the multilayer reflective film 2. The number of periods was 40 periods here, but the number of periods is not limited to this number and may be, for example, 60 periods. In the case of 60 periods, the number of steps is larger than the number of steps in the case of 40 periods, but reflectance for EUV light can be increased.

Subsequently, the protective film 3 including a Ru film was formed with a thickness of 2.5 nm by an ion beam sputtering method using a Ru target in the Ar gas atmosphere.

Next, the absorber film 4 including a SnTa film was formed by a direct current (DC) magnetron sputtering method. The SnTa film was formed with a film thickness of 39.0 nm using a SnTa target by reactive sputtering in an Ar gas atmosphere.

The element ratio of the SnTa film was 50 atomic % of Sn and 50 atomic % of Ta. In addition, the crystal structure of the SnTa film was measured by an X-ray diffractometer (XRD) to find that the SnTa film had an amorphous structure. In addition, a refractive index n of the SnTa film at a wavelength of 13.5 nm was approximately 0.930, and an extinction coefficient k thereof was approximately 0.054.

Reflectance of the absorber film 4 including the SnTa film at a wavelength of 13.5 nm was 1%.

Cleaning resistance of the absorber film 4 made of the SnTa film was evaluated by sulfuric-acid and hydrogen-peroxide mixture (SPM) cleaning. Conditions of the SPM cleaning were as follows. Sulfuric acid:hydrogen peroxide water=2:1 (volume ratio), a temperature of 80 to 100° C., and an immersion time of 30 minutes. The cleaning resistance of the SnTa film was high and no film loss was observed.

Next, using the reflective mask blank 100 of Example 1 described above, the reflective mask 200 of Example 1 was manufactured.

As described above, the resist film 11 was formed with a thickness of 150 nm on the absorber film 4 of the reflective mask blank 100 (FIG. 2(a)). Then, a desired pattern was drawn (exposed) on this resist film 11 and was further developed and rinsed, whereby a predetermined resist pattern 11 a was formed (FIG. 2(b)). Next, using the resist pattern 11a as a mask, the SnTa film (the absorber film 4) was subjected to dry etching using a Cl₂ gas. As a result, the absorber pattern 4a was formed (FIG. 2(c)). The SnTa film had sufficient resistance to dry etching to successfully form a pattern without melting.

Thereafter, the resist pattern 11a was removed by ashing, a resist stripping solution, or the like. Finally, wet cleaning was performed using deionized water (DIW) to manufacture the reflective mask 200 (FIG. 2(d)). Note that a mask defect inspection can be performed as necessary after the wet cleaning, and a mask defect can be corrected appropriately.

Regarding the reflective mask 200 of Example 1, it was confirmed that electron beam drawing on the resist film 11 on the SnTa film produced a drawn pattern in accordance with design values. In addition, since the SnTa film was made of an amorphous alloy, the processability with a chlorine-based gas was good and the absorber pattern 4a could be formed with high accuracy. In addition, the film thickness of the absorber pattern 4a was 39.0 nm and was made thinner than that of the absorber film 4 formed of a conventional Ta-based material, and thus the shadowing effect was reduced.

The reflective mask 200 manufactured in Example 1 was set in an EUV exposure scanner, and EUV exposure was performed on a wafer on which a film to be processed and a resist film were formed on a semiconductor substrate. The SnTa film had sufficient resistance against EUV exposure. Then, the resist film that has been subjected to the exposure was developed, whereby a resist pattern was formed on the semiconductor substrate on which the film to be processed was formed.

Additionally, this resist pattern was transferred on the film to be processed by etching, and a semiconductor device having desired characteristics was manufactured through various steps such as formation of an insulating film and a conductive film, introduction of a dopant, and annealing.

### Example 2

Example 2 was similar to Example 1 except that the absorber film 4 was made of an amorphous alloy of SnNiN.

Accordingly, the absorber film 4 including a SnNiN film was formed by a direct current (DC) magnetron sputtering method. The SnNiN film was formed with a film thickness of 40.0 nm using a SnNi target by reactive sputtering in the Ar/N₂ gas atmosphere.

The element ratio of the SnNiN film was 45 atomic % of Sn, 45 atomic % of Ni, and 10 atomic % of N. In addition, the crystal structure of the SnNiN film was measured by an X-ray diffractometer (XRD) to find that the SnNiN film had an amorphous structure. In addition, a refractive index n of the SnNiN film at a wavelength of 13.5 nm was approximately 0.935, and an extinction coefficient k thereof was approximately 0.066.

Reflectance of the absorber film 4 including the SnNiN film at a wavelength of 13.5 nm was 0.1%.

As in Example 1, the SPM cleaning resistance of the SnNiN film was high and no film loss was observed.

In addition, the reflective mask 200 and a semiconductor device of Example 2 were manufactured in the same manner as in Example 1, and good results were obtained as in Example 1.

That is, as in Example 1, regarding the reflective mask 200 of Example 2, it was confirmed that electron beam drawing on the resist film 11 produced a drawn pattern in accordance with design values. Since the absorber film 4 was made of an amorphous alloy, the processability with a chlorine-based gas was good and the absorber pattern 4a could be formed with high accuracy. The film thickness of the absorber pattern 4a of Example 2 was 40.0 nm and was made thinner than that of the absorber film 4 formed of a conventional Ta-based material, and thus the shadowing effect was reduced. Therefore, by using the reflective mask 200 manufactured in Example 2, a semiconductor device having desired characteristics was manufactured.

### Example 3

Example 3 was similar to Example 1 except that the absorber film 4 was a SnCo film made of an amorphous metal.

Accordingly, the absorber film 4 including a SnCo film was formed by a direct current (DC) magnetron sputtering method. The SnCo film was formed with a film thickness of 40.0 nm using a SnCo target by reactive sputtering in an Ar gas atmosphere.

The element ratio of the SnCo film was 50 atomic % of Sn and 50 atomic % of Co. In addition, the crystal structure of the SnCo film was measured by an X-ray diffractometer (XRD) to find that the SnCo film had an amorphous structure. In addition, a refractive index n of the SnCo film at a wavelength of 13.5 nm was approximately 0.925, and an extinction coefficient k thereof was approximately 0.070.

Reflectance of the absorber film 4 including the SnCo film at a wavelength of 13.5 nm was 0.009%.

As in Example 1, the SPM cleaning resistance of the SnCo film was high and no film loss was observed.

In addition, the reflective mask 200 and a semiconductor device of Example 3 were manufactured in the same manner as in Example 1, and good results were obtained as in Example 1.

That is, as in Example 1, regarding the reflective mask 200 of Example 3, it was confirmed that electron beam drawing on the resist film 11 produced a drawn pattern in accordance with design values. Since the absorber film 4 was made of an amorphous alloy, the processability with a chlorine-based gas was good and the absorber pattern 4a could be formed with high accuracy. The film thickness of the absorber pattern 4a of Example 3 was 40.0 nm and was made thinner than that of the absorber film 4 formed of a conventional Ta-based material, and thus the shadowing effect was reduced. Therefore, by using the reflective mask 200 manufactured in Example 3, a semiconductor device having desired characteristics was manufactured.

### Example 4

Example 4 was similar to Example 1 except that the absorber film 4 included a SnTa film made of an amorphous metal having an element ratio and a film thickness different from those in Example 1.

Accordingly, the absorber film 4 including a SnTa film was formed by a direct current (DC) magnetron sputtering method. The SnTa film was formed with a film thickness of 32.7 nm using a SnTa target by reactive sputtering in an Ar gas atmosphere.

The element ratio of the SnTa film was 67 atomic % of Sn and 33 atomic % of Ta. In addition, the crystal structure of the SnTa film was measured by an X-ray diffractometer (XRD) to find that the SnTa film had an amorphous structure. In addition, a refractive index n of the SnTa film at a wavelength of 13.5 nm was approximately 0.928, and an extinction coefficient k thereof was approximately 0.055.

Reflectance of the absorber film 4 including the SnTa film at a wavelength of 13.5 nm was 1.1%.

As in Example 1, the SPM cleaning resistance of the SnTa film was high and no film loss was observed.

In addition, the reflective mask 200 and a semiconductor device of Example 4 were manufactured in the same manner as in Example 1, and good results were obtained as in Example 1.

That is, as in Example 1, regarding the reflective mask 200 of Example 4, it was confirmed that electron beam drawing on the resist film 11 produced a drawn pattern in accordance with design values. Since the absorber film 4 was made of an amorphous alloy, the processability with a chlorine-based gas was good and the absorber pattern 4a could be formed with high accuracy. The film thickness of the absorber pattern 4a of Example 4 was 32.7 nm and was made thinner than that of the absorber film 4 formed of a conventional Ta-based material, and thus the shadowing effect was reduced. Therefore, by using the reflective mask 200 manufactured in Example 4, a semiconductor device having desired characteristics was manufactured.

### Example 5

In Example 5, as shown in FIG. 6, the etching mask film 6 was included in the reflective mask blank 300. Example 5 was similar to Example 1 except that the absorber film 4 was made of a SnTa amorphous alloy and the etching mask film 6 including a CrN film was provided on the absorber film 4.

As the etching mask film 6, a CrN film was formed on a substrate with an absorber film prepared in the same manner as in Example 1 by a magnetron sputtering (reactive sputtering) method under the following conditions to obtain the reflective mask blank 300 of Example 5.

Conditions for forming the etching mask film 6: a Cr target, a mixed gas atmosphere of Ar and N₂ (Ar: 90%, N: 10%), and a film thickness of 10 nm.

The elemental composition of the etching mask film 6 was measured by Rutherford backscattering spectroscopy to find Cr: 90 atomic % and N: 10 atomic %.

Next, using the reflective mask blank 300 of Example 5 described above, the reflective mask 400 of Example 5 was manufactured.

The resist film 11 was formed with a thickness of 100 nm on the etching mask film 6 of the reflective mask blank 300 (FIG. 7(a)). Then, a desired pattern was drawn (exposed) on this resist film 11 and was further developed and rinsed, whereby a predetermined resist pattern 11a was formed (FIG. 7(b)). Next, using the resist pattern 11a as a mask, the CrN film (the etching mask film 6) was subjected to dry etching using a mixed gas of a Cl₂ gas and O₂ (Cl₂+O₂ gas). As a result, the etching mask pattern 6a was formed (FIG. 7(c)). Subsequently, the SnTa film (the absorber film 4) was subjected to dry etching using a Cl₂ gas. As a result, the absorber pattern 4a was formed. The resist pattern 11a was removed by ashing, a resist stripping solution, or the like (FIG. 7(d)).

Then, the etching mask pattern 6a was removed by dry etching with a mixed gas of a Cl₂ gas and O₂ (FIG. 7(e)). Finally, wet cleaning was performed with deionized water (DIW) to manufacture the reflective mask 400 of Example 5.

Since the etching mask film 6 was formed on the absorber film 4, the absorber film 4 could be easily etched. Furthermore, the resist film 11 for forming the transfer pattern could be thinned, and the reflective mask 400 having a fine pattern could be obtained.

Regarding the reflective mask 400 of Example 5, it was confirmed that electron beam drawing on the resist film 11 on the SnTa film produced a drawn pattern in accordance with design values. In addition, since the SnTa film was made of an amorphous alloy and the etching mask film 6 was provided on the absorber film 4, the absorber pattern 4a could be formed with high accuracy. In addition, the film thickness of the absorber pattern 4a was 39.0 nm and was made thinner than that of the absorber film 4 formed of a conventional Ta-based material, and thus the shadowing effect was reduced.

The reflective mask 400 manufactured in Example 5 was set in an EUV exposure scanner, and EUV exposure was performed on a wafer on which a film to be processed and a resist film were formed on a semiconductor substrate. Then, the resist film that has been subjected to the exposure was developed, whereby a resist pattern was formed on the semiconductor substrate on which the film to be processed was formed.

Additionally, this resist pattern was transferred on the film to be processed by etching, and a semiconductor device having desired characteristics was manufactured through various steps such as formation of an insulating film and a conductive film, introduction of a dopant, and annealing.

### Comparative Example 1

In Comparative Example 1, a reflective mask blank 100 and a reflective mask 200 were each manufactured to have a structure similar to that in Example 1 by a method similar to that in Example 1, and a semiconductor device was manufactured by a method similar to that in Example 1, except that in Comparative Example 1, a single-layer TaBN film was used as an absorber film 4.

In place of the SnTa film, the single-layer TaBN film was formed on a protective film 3 having a mask blank structure of Example 1. The TaBN film was formed with a film thickness of 62 nm using a TaB mixed sintering target by reactive sputtering in a mixed gas atmosphere of Ar gas and N₂ gas.

The element ratio of the TaBN film was 75 atomic % of Ta, 12 atomic % of B, and 13 atomic % of N. A refractive index n of the TaBN film at a wavelength of 13.5 nm was approximately 0.949, and an extinction coefficient k thereof was approximately 0.030.

Reflectance of the absorber film 4 including the above-described single-layer TaBN film at a wavelength of 13.5 nm was 1.4%. In the case of a TaBN film, since its extinction coefficient k is as low as about 0.030, the film thickness needs to be 60 nm or more in order to have reflectance of 2% or less. Therefore, when the TaBN film is used as the absorber film 4, it is difficult to reduce the shadowing effect.

Thereafter, a resist film 11 was formed on the absorber film 4 including the TaBN film by a method similar to that in Example 1, and a desired pattern was drawn (exposed), and developed and rinsed, whereby a resist pattern 11a was formed. Then, using the resist pattern 11a as a mask, the absorber film 4 including the TaBN film was subjected to dry etching using a chlorine gas to form an absorber pattern 4a. Removal of the resist pattern 11a, cleaning of the mask, and the like were performed in the same manner as that in Example 1 to manufacture the reflective mask 200 of Comparative Example 1.

The film thickness of the absorber pattern 4a was 62 nm, and the shadowing effect could not be reduced. That is, as a result of electron beam drawing on the resist film 11, it was confirmed that the reflective mask 200 of Comparative Example 1 was deviated from design values due to the shadowing effect.

### REFERENCE SIGNS LIST

1 Substrate

2 Multilayer reflective film

3 Protective film

4 Absorber film

4a Absorber pattern

5 Conductive back film

6 Etching mask film

6a Etching mask pattern

7 Etching stopper film

7a Etching stopper pattern

11 Resist film

11a Resist pattern

100, 300, 500 Reflective mask blank

200, 400, 600 Reflective mask

1. A reflective mask blank comprising:
a multilayer reflective film provided on a substrate; and
an absorber film provided on the multilayer reflective film,
wherein the absorber film includes an amorphous metal containing Tin (Sn) and at least one element selected from tantalum (Ta), chromium (Cr), cobalt (Co), nickel (Ni), antimony (Sb), platinum (Pt), iridium (Ir), iron (Fe), gold (Au), aluminum (Al), copper (Cu), zinc (Zn), and silver (Ag), and
wherein a film thickness of the absorber film is 55 nm or less.

2. The reflective mask blank according to claim 1, wherein content of the tin (Sn) is 10 atomic % or more and 90 atomic % or less.

3. The reflective mask blank according to claim 1,
wherein an extinction coefficient of the absorber film is 0.035 or more, and
wherein the amorphous metal contains tin (Sn) and at least one element selected from tantalum (Ta), chromium (Cr), platinum (Pt), iridium (Ir), iron (Fe), gold (Au), aluminum (Al), and zinc (Zn).

4. The reflective mask blank according to claim 1,
wherein an extinction coefficient of the absorber film is 0.045 or more, and
wherein the amorphous metal contains tin (Sn) and at least one element selected from cobalt (Co), nickel (Ni), antimony (Sb), copper (Cu), and silver (Ag).

5. The reflective mask blank according to claim 1,
wherein the amorphous metal contains tin (Sn) and at least one element selected from tantalum (Ta) and chromium (Cr), and
wherein content of the tantalum (Ta) in the amorphous metal is more than 15 atomic %.

6. The reflective mask blank according to claim 1,
wherein the amorphous metal contains nitrogen (N), and
wherein content of the nitrogen (N) in the amorphous metal is 2 atomic % or more and 55 atomic % or less.

7. The reflective mask blank according to claim 1, wherein a protective film is provided between the multilayer reflective film and the absorber film.

8. The reflective mask blank according to claim 1, wherein an etching mask film is provided on the absorber film, and wherein the etching mask film includes chromium (Cr) or silicon (Si).

9. A reflective mask comprising a multilayer reflective film provided on a substrate and an absorber pattern provided on the multilayer reflective film,
wherein the absorber pattern includes an amorphous metal containing Tin (Sn) and at least one element selected from tantalum (Ta), chromium (Cr), cobalt (Co), nickel (Ni), antimony (Sb), platinum (Pt), iridium (Ir), iron (Fe), gold (Au), aluminum (Al), copper (Cu), zinc (Zn), and silver (Ag), and
wherein a film thickness of the absorber film is 55 nm or less.

10. A method of manufacturing a reflective mask, the method comprising forming an absorber pattern by patterning the absorber film of the reflective mask blank according to claim 1 by dry etching using a chlorine-based gas.

11. A method of manufacturing a semiconductor device, the method comprising setting the reflective mask according to claim 9 in an exposure apparatus having an exposure light source that emits EUV light and transferring a transfer pattern to a resist film formed on a transfer-receiving substrate.

12. The reflective mask according to claim 9, wherein content of the tin (Sn) is 10 atomic % or more and 90 atomic % or less.

13. The reflective mask according to claim 9, wherein an extinction coefficient of the absorber film is 0.035 or more, and
wherein the amorphous metal contains tin (Sn) and at least one element selected from tantalum (Ta), chromium (Cr), platinum (Pt), iridium (Ir), iron (Fe), gold (Au), aluminum (Al), and zinc (Zn).

14. The reflective mask according to claim 9, wherein an extinction coefficient of the absorber film is 0.045 or more, and
wherein the amorphous metal contains tin (Sn) and at least one element selected from cobalt (Co), nickel (Ni), antimony (Sb), copper (Cu), and silver (Ag).

15. The reflective mask according to claim 9, wherein the amorphous metal contains tin (Sn) and at least one element selected from tantalum (Ta) and chromium (Cr), and
wherein content of the tantalum (Ta) in the amorphous metal is more than 15 atomic %.

16. The reflective mask according to claim 9,
wherein the amorphous metal contains nitrogen (N), and
wherein content of the nitrogen (N) in the amorphous metal is 2 atomic % or more and 55 atomic % or less.

17. The reflective mask according to claim 9, wherein a protective film is provided between the multilayer reflective film and the absorber pattern.
